(19) United States
(12) Patent Application Publication
(10) Pub. No.: US 2025/0300050 A1
(43) Pub. Date: Sep. 25, 2025

(54) PACKAGE SUBSTRATE

(71) Applicant: QUALCOMM Incorporated, San Diego, CA (US)

(72) Inventors: Kuiwon KANG, San Diego, CA (US); Omar James BCHIR, San Marcos, CA (US); Hong Bok WE, San Diego, CA (US); Seongryul CHOI, Seongnam (KR)

(21) Appl. No.: 18/609,459

(22) Filed: Mar. 19, 2024

(51) Int. Cl. H01L 23/498; H01L 21/48; H01L 23/522; H01L 23/528

(52) U.S. Cl. CPC H01L 23/49822; H01L 21/4857; H01L 23/5226; H01L 23/5283

(57) ABSTRACT

Disclosed are techniques for a structure of a package substrate. In an aspect, a package substrate includes a core dielectric that includes a first surface, a second surface, and a first cavity through the core dielectric. The EPS structure includes a first metallization structure on the first surface of the core dielectric and a second metallization structure on the second surface of the core dielectric. The first metallization structure includes a first plurality of dielectric layers, and the second metallization structure includes a second plurality of dielectric layers. The EPS structure further includes a first embedded component disposed in the first cavity and through at least the core dielectric, one of the first plurality of dielectric layers immediately adjacent the first surface of the core dielectric, and one of the second plurality of dielectric layers immediately adjacent the second surface of the core dielectric.

### TECHNICAL FIELD

The present disclosure generally relates to a structure of a package substrate, and more particularly, to an embedded package substrate (EPS) structure capable of accommodating various embedded components with different thicknesses.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-die devices and system on a chip (SOC) devices, which may include multiple function blocks, with each function block designed to perform a specific function, such as, for example, a microprocessor function, a graphics processing unit (GPU) function, a communications function (e.g., Wi-Fi, Bluetooth, and other communications), and the like.

In some implementations, a package substrate may include an embedded package substrate (EPS) structure incorporating one or more embedded components and metallization structures for performance improvement and package size reduction. In some implementations, an embedded component may include embedded active devices (e.g., one or more transistors or diodes) and/or embedded passive devices (e.g., deep trench capacitors). The thickness of the one or more embedded components may vary and may be determined by various suppliers of the embedded components. Also, a thickness of a metallization structure of the EPS structure may affect an alternating current inductance (AC-L) of a conductive path from a conductive terminal of an embedded component to an external circuit through the metallization structure.

Accordingly, there is a need for an improved EPS structure for a package substrate and a method of making such package substrate that can accommodate various embedded components with different thicknesses and can maintain the AC-L at a desirable level regardless of the thicknesses of the embedded components and/or the metallization structures of such package substrate.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a package substrate includes a core dielectric that includes a first surface, a second surface, and a first cavity through the core dielectric from the first surface to the second surface; a first metallization structure on the first surface of the core dielectric, the first metallization structure including a first plurality of dielectric layers with first conductive traces and first conductive vias disposed therein; a second metallization structure on the second surface of the core dielectric including a second plurality of dielectric layers with second conductive traces and second conductive vias disposed therein; and a first embedded component disposed in the first cavity and through at least the core dielectric, one of the first plurality of dielectric layers immediately adjacent the first surface of the core dielectric, and one of the second plurality of dielectric layers immediately adjacent the second surface of the core dielectric.

In an aspect, a method of manufacturing a package substrate includes forming a first cavity of a core dielectric, the core dielectric including a first surface and a second surface, and the first cavity through the core dielectric from the first surface to the second surface; forming a first metallization structure on the first surface of the core dielectric, the first metallization structure including a first plurality of dielectric layers with first conductive traces and first conductive vias disposed therein; forming a second metallization structure on the second surface of the core dielectric including a second plurality of dielectric layers with second conductive traces and second conductive vias disposed therein; and disposing a first embedded component in the first cavity and through at least the core dielectric, one of the first plurality of dielectric layers immediately adjacent the first surface of the core dielectric, and one of the first plurality of dielectric layers immediately adjacent the second surface of the core dielectric.

In an aspect, an electronic device includes a package substrate that includes: a core dielectric that includes a first surface, a second surface, and a first cavity through the core dielectric from the first surface to the second surface; a first metallization structure on the first surface of the core dielectric, the first metallization structure including a first plurality of dielectric layers with first conductive traces and first conductive vias disposed therein; a second metallization structure on the second surface of the core dielectric including a second plurality of dielectric layers with second conductive traces and second conductive vias disposed therein; and a first embedded component disposed in the first cavity and through at least the core dielectric, one of the first plurality of dielectric layers immediately adjacent the first surface of the core dielectric, and one of the first plurality of dielectric layers immediately adjacent the second surface of the core dielectric.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 is a cross-sectional view of an example embedded package substrate (EPS) structure of a package substrate, according to aspects of the disclosure.

FIG. 2 is a cross-sectional view of an example deep trench capacitor (DTC), according to aspects of the disclosure.

FIGS. 3A-3K illustrate structures at various stages of manufacturing an EPS structure of FIG. 1, according to aspects of the disclosure.

FIG. 4 illustrates a method for manufacturing a package substrate, according to aspects of the disclosure.

FIG. 5 illustrates a simplified cross-sectional view of an IC package that includes a package substrate having an EPS structure, according to aspects of the disclosure.

FIG. 6 illustrates a method of fabricating an IC package that includes an EPS structure, according to aspects of the disclosure.

FIG. 7 illustrates various electronic devices that may integrate an IC package that includes a package substrate described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to an embedded package substrate (EPS) structure of a package substrate suitable of accommodating an embedded component of any thickness, and a manufacturing method of making the package substrate.

Particular aspects of the subject matter described in this disclosure can be implemented to realize one or more of the following potential advantages. In some examples, the thickness of a core dielectric of the EPS structure may not be limited by the thicknesses of the embedded components to be included therein. In some examples, by moving the conductive terminals of an embedded component closer to an outer surface of the EPS structure, an alternating current inductance (AC-L) of a conductive path from the embedded component to the external circuitry may be reduced to a desirable level. Accordingly, the number of dielectric/conductive layers of the EPS structure may be increased to allow a more complicated routing scheme while still reducing the AC-L regarding the embedded component.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

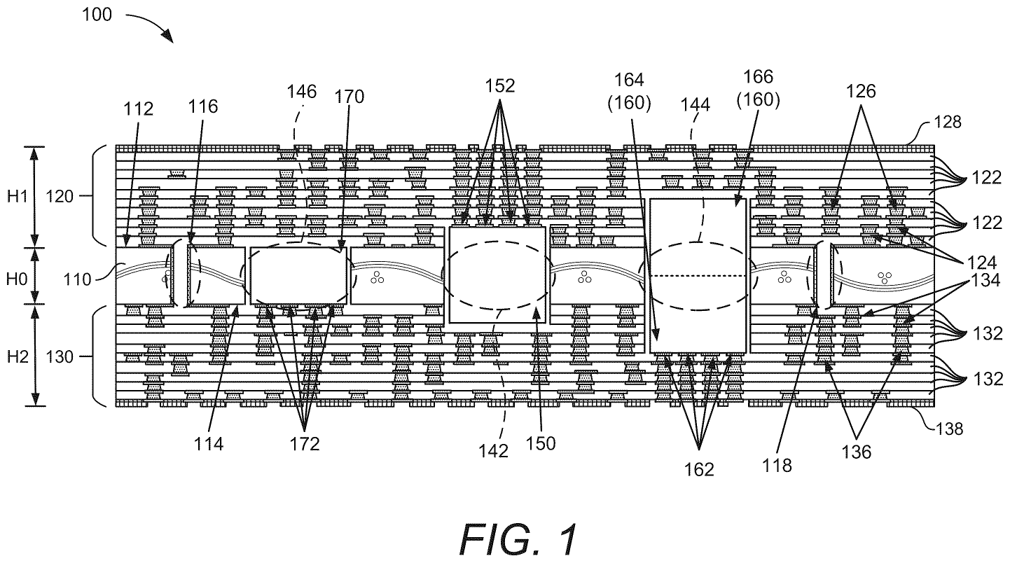

FIG. 1 is a cross-sectional view of an embedded package substrate (EPS) structure 100 of a package substrate, according to aspects of the disclosure. In some aspects, the EPS structure 100 may correspond to a portion of the package substrate and may be depicted as a simplified example of an EPS structure.

As shown in FIG. 1, the EPS structure 100 includes a core dielectric 110 that includes a first surface 112 and a second surface 114. In some aspects, the core dielectric 110 may further include through substrate via structures 116 and 118 passing through the core dielectric 110 and configured to electrically coupling respective conductive features on the first surface 112 and the second surface 114. In some aspects, the core dielectric 110 may include resin or fiber-reinforced composite resin. The core dielectric 110 may have a thickness of H0. In some aspects, the thickness H0 may range from 150 micrometers (μm) to 500 μm.

The EPS structure 100 further includes a first metallization structure 120 on the first surface 112 of the core dielectric 110 at a first side of the core dielectric 110; and a second metallization structure 130 on the second surface 114 of the core dielectric 110 at a second side of the core dielectric 110. In some aspects, the first metallization structure 120 may include a first plurality of dielectric layers 122 with first conductive traces 124 (only some of those are labeled in FIG. 1 as examples) and first conductive vias 126 (only some of those are labeled in FIG. 1 as examples) disposed therein. In some aspects, the first metallization structure 120 may include a first protective layer 128 on the first plurality of dielectric layers 122, the first conductive traces 124, and the first conductive vias 126. In some aspects, the second metallization structure 130 may include a second plurality of dielectric layers 132 with second conductive traces 134 (only some of those are labeled in FIG. 1 as examples) and second conductive vias 136 (only some of those are labeled in FIG. 1 as examples) disposed therein. In some aspects, the second metallization structure 130 may include a second protective layer 138 on the second plurality of dielectric layers 132, the second conductive traces 134, and the second conductive vias 136.

In some aspects, the first plurality of dielectric layers includes six (6) or more dielectric layers. In some aspects, the second plurality of dielectric layers includes six (6) or more dielectric layers. In some aspects, each dielectric layer of the first plurality of dielectric layers 122 and the second plurality of dielectric layers 132 may be based on a respective build-up dielectric film. In some aspects, the build-up dielectric film may be a pre-preg dielectric film, an Ajinomoto build-up film (ABF), or the like. In some aspects, the first metallization structure 120 may have a thickness of H1, and the second metallization structure 130 may have a thickness of H2. In some aspects, the thickness H1 may range from 150 micrometers μm to 700 μm. In some aspects, the thickness H2 may range from 150 micrometers μm to 700 μm.

In some aspects, an embedded component that is disposed in the core dielectric 110, without using the method described in this disclosure, may have an AC-L based on a conductive path length of at least the entire thickness of the first metallization structure 120 (e.g., H1) or the second metallization structure 130 (e.g., H1). In some aspects, when the IC package is designed with a more complicated routing scheme, a number of the dielectric/conductive layers of the first metallization structure 120 or the second metallization structure 130 may be increased, and the AC-L may increase as the conductive path length increases. In some aspects, a metallization structure with five (5) dielectric/conductive layers may have a thickness of about 205 μm; a metallization structure with seven (7) dielectric/conductive layers may have a thickness of about 285 μm; a metallization structure with eight (8) dielectric/conductive layers may have a thickness of about 450 μm; a metallization structure with nine (9) dielectric/conductive layers may have a thickness of about 500 μm; and a metallization structure with eleven (11) dielectric/conductive layers may have a thickness of about 600 μm.

In this example, the core dielectric 110 includes cavities 142, 144, and 146 in the core dielectric 110 or through the core dielectric 110 from the first surface 112 to the second surface 114. In some aspects, the EPS structure 100 may include a first embedded component 150 disposed in the cavity 142 and through at least the core dielectric 110, one of the first plurality of dielectric layers 122 immediately adjacent the first surface of the core dielectric, and one of the second plurality of dielectric layers 132 immediately adjacent the second surface of the core dielectric. In some aspects, the first embedded component 150 may be disposed through a first number of dielectric layers of the first plurality of dielectric layers 122 and through a second number of dielectric layers of the second plurality of dielectric layers 132. In some aspects, the first number may equal the second number (e.g., both being two in this example). In some aspects, the first number may be different from the second number, depending on the thickness of the first embedded component 150, the thickness of the core dielectric 110, and/or the layer build-up process of the first metallization structure 130 and the second metallization structure 130.

In some aspects, the EPS structure 100 may include a second embedded component 160 disposed in the cavity 144 and through at least the core dielectric 110, one of the first plurality of dielectric layers 122 immediately adjacent the first surface of the core dielectric, and one of the second plurality of dielectric layers 132 immediately adjacent the second surface of the core dielectric. In some aspects, a first thickness of the first embedded component and a second thickness of the second embedded component may be different. In some aspects, the first thickness of the first embedded component and the second thickness of the second embedded component may be greater than the thickness H0 of the core dielectric 110.

In some aspects, the second embedded component 160 may be disposed through a third number of dielectric layers of the first plurality of dielectric layers 122 and through a fourth number of dielectric layers of the second plurality of dielectric layers 132. In some aspects, the third number may equal the fourth number (e.g., both being five in this example). In some aspects, the third number may be different from the fourth number, depending on the thickness of the first embedded component 160, the thickness of the core dielectric 110, and/or the layer build-up process of the first metallization structure 130 and the second metallization structure 130.

As shown in FIG. 1, the first embedded component 150 may include first conductive terminals 152 disposed at the first side of the core dielectric 110; and the second embedded component 160 may include second conductive terminals 162 disposed at the second side of the core dielectric 110. In some aspects, the first conductive terminals 152 and the second conductive terminals 162 may be disposed at a same side of the core dielectric 110 or at different sides of the core dielectric 110.

Furthermore, as shown in FIG. 1, the EPS structure 100 may include a third embedded component 170 disposed in the cavity 146 of the core dielectric 110, without passing through the one of the first plurality of dielectric layers 122 immediately adjacent the first surface 112 of the core dielectric 110, and without passing through the one of the second plurality of dielectric layers 132 immediately adjacent the second surface 114 of the core dielectric 110. In some aspects, a third thickness of the third embedded component may be less than a summation of the thickness H0 of the core dielectric 110 and twice the thickness of a build-up dielectric film used to form various layers of the first plurality of dielectric layers 122 and the second plurality of dielectric layers 132. In some aspects, the third thickness of the third embedded component may be equal to or less than the thickness H0 of the core dielectric 110.

In some aspects, the AC-L regarding the third embedded component 170 may be greater than those of the first embedded component 150 and the second embedded component 160, as the conductive path length from the third embedded component 170 to the external circuitry outside the EPS structure 100 may be longer than those for the first embedded component 150 and the second embedded component 160.

In some aspects, although the EPS structure 100 including three embedded components 150, 160, and 170 is depicted in FIG. 1 as a non-limiting example, an EPS structure may include any number of embedded components with any thickness that is less than the summation of the thickness H0 of the core dielectric 110, the thickness H1 of the first metallization structure 120, and the thickness H2 of the second metallization structure 130.

In some aspects, the EPS structure 100 illustrated in FIG. 1 may accommodate an embedded component of any thickness. Accordingly, the thickness of the core dielectric 110 may not be limited by the thicknesses of the embedded components to be included therein. In some aspects, the EPS structure 100 illustrated in FIG. 1 may be used to move the conductive terminals of an embedded component toward an outer surface of the EPS structure 100, such that the AC-L of a conductive path from the embedded component to the external circuitry may be reduced to a desirable level. Accordingly, the number of dielectric/conductive layers of the first metallization structure 120 and/or the second metallization structure 130 may be increased to allow a more complicated routing scheme while still reducing the AC-L regarding an embedded component.

In some aspects, an embedded component included in the EPS structure 100 may include a single chip, such as the first embedded component 150 and the third embedded component 170. In some aspects, an embedded component included in the EPS structure 100 may include a chip and a dummy structure stacked one over the other, such as the second embedded component 160 having a chip 164 and a dummy structure 166 stacked one over the other in order to increase the overall thickness of the embedded component 160. In some aspects, the dummy structure 166 may be introduced to reduce the length of a conductive path from one of the conductive terminals 162 to a lower surface of the EPS structure 100 and thus reduce the AC-L regarding the second embedded component 160.

In some aspects, an embedded component included in the EPS structure 100 may include (e.g., in the chip of the embedded component) a capacitive device, an inductive device, a resistive device, an active device, or any combination thereof.

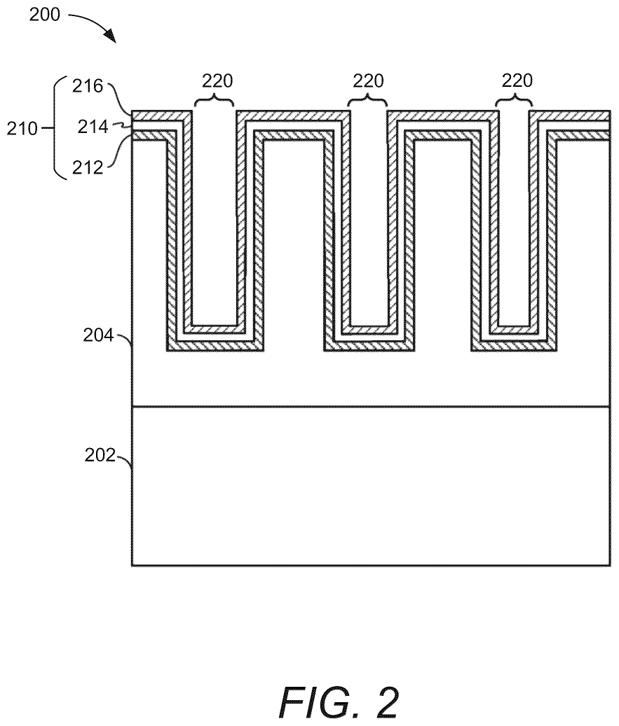

According to certain aspects of the disclosure, the capacitive device may be a deep trench capacitor (DTC). FIG. 2 is a cross-sectional view of an example DTC 200, according to aspects of the disclosure. In some aspects, each one of the first embedded component 150, the second embedded component 160, and/or the third embedded component 170 may include a structure corresponding to the example DTC 200.

As shown in FIG. 2, a capacitor 210 is formed in trenches 220 of an insulator 204 on a substrate 202. The capacitor 210 may include a first metal layer 212, a dielectric layer 214, and a second metal layer 216. The dielectric layer 214 separates the first metal layer 212 from the second metal layer 216. The first metal layer 212 and the second metal layer 216 may form electrodes of the capacitor 210 and may be connected to conductive terminals at, for example, a surface (see, e.g., the conductive terminals 152, 162, and/or 172 shown in FIG. 1). In some scenarios, the capacitors may be formed from an array of deep trenches in a substrate and filled with an electrical insulator (e.g., a dielectric) between layers of electrodes.

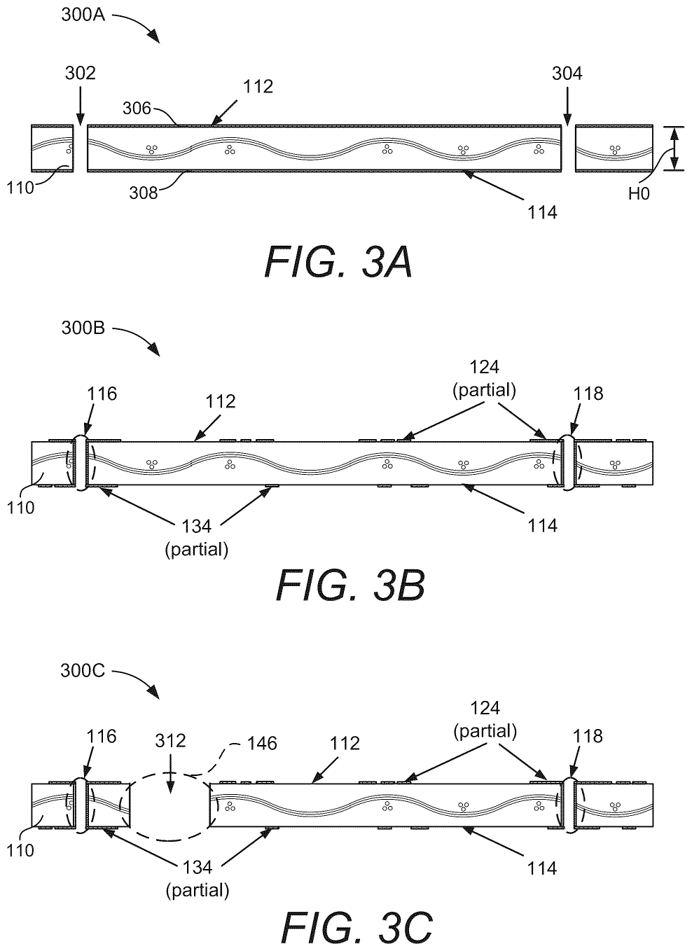

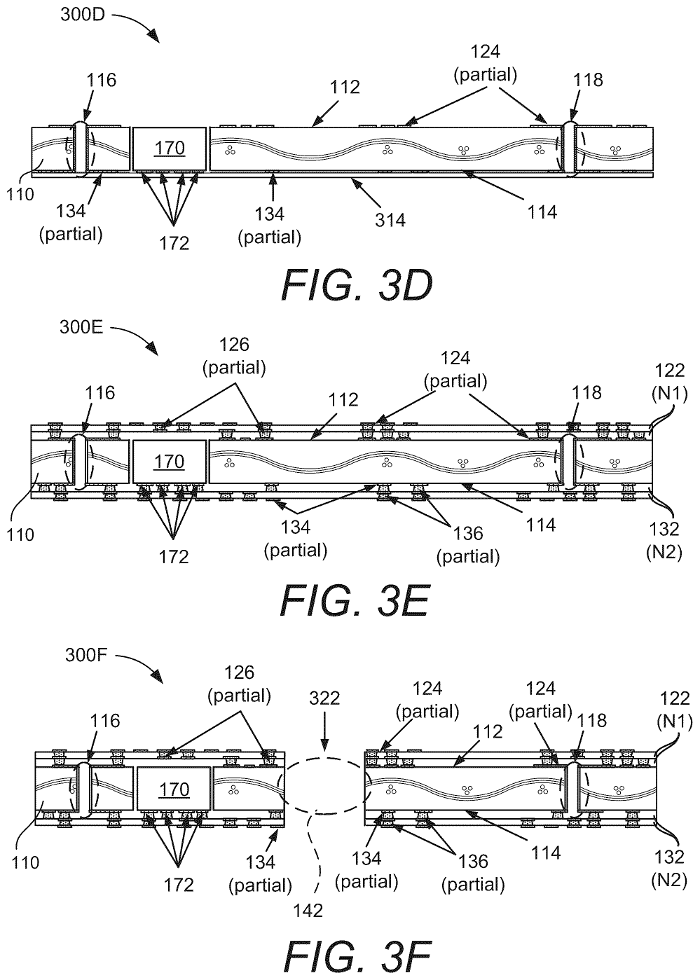

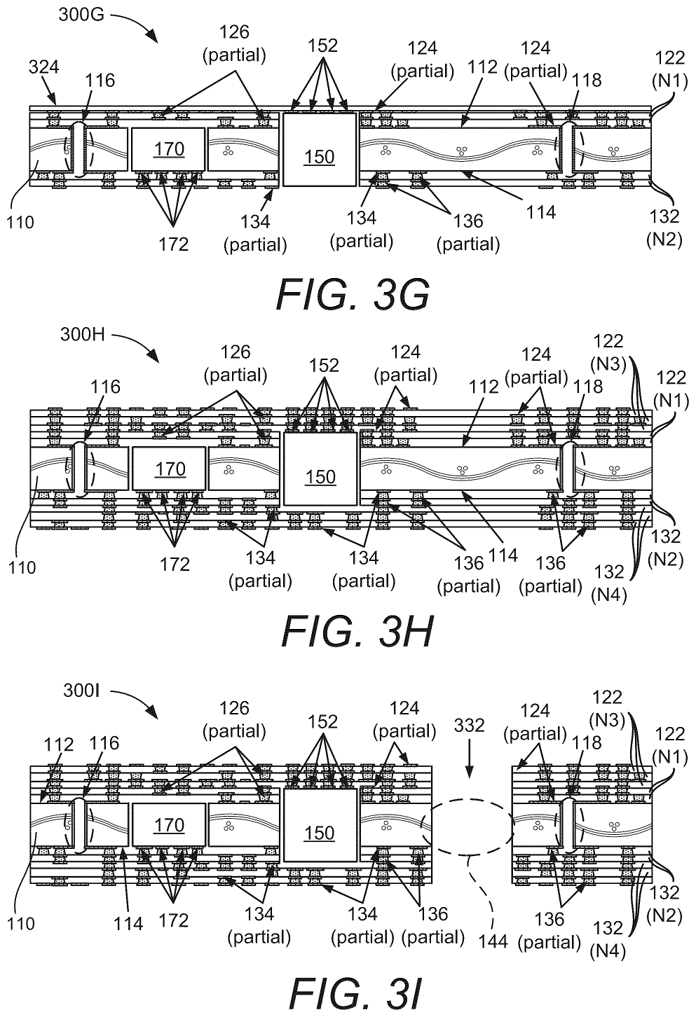

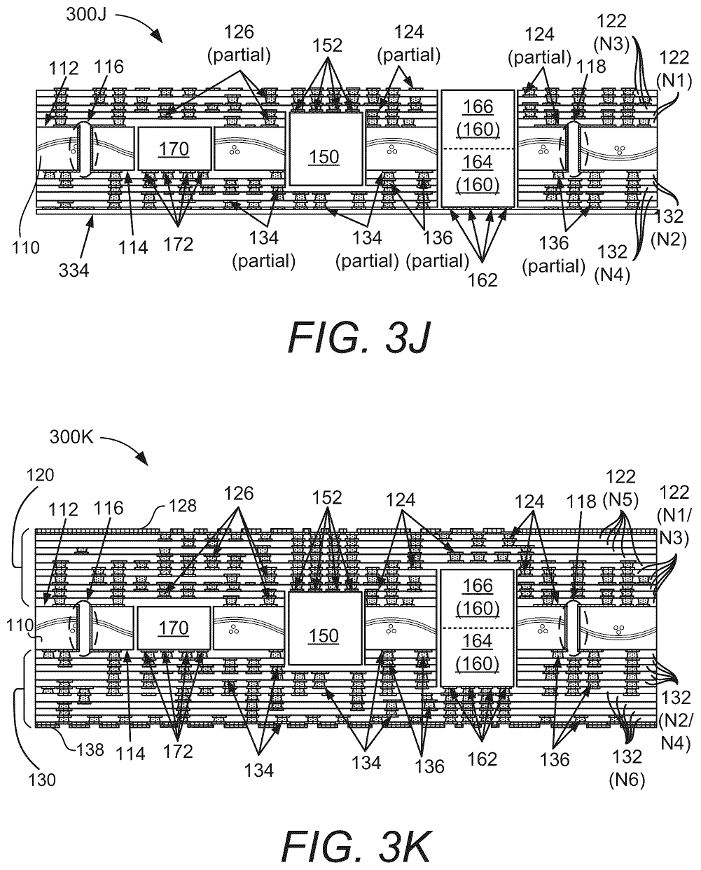

FIGS. 3A-3K illustrate structures at various stages of manufacturing an EPS structure of FIG. 1 (e.g., the EPS structure 100 of a package substrate), according to aspects of the disclosure. The components illustrated in FIGS. 3A-3K that are the same or similar to those of FIG. 1 are given the same reference numbers, and the detailed description thereof may be omitted.

As shown in FIG. 3A, a structure 300A which includes a core dielectric 110 is provided. The core dielectric 110 may be part of and/or based on a core substrate, such as a copper clad laminate (CCL) core. The core dielectric 110 may include a first surface 112 at a first side of the core dielectric 110 and a second surface 114 at a second side of the core dielectric 110. In some aspects, the core dielectric 110 may include resin or fiber-reinforced composite resin. The core dielectric 110 may have a thickness of H0. In some aspects, the thickness H0 may range from 150 micrometers μm to 500 μm.

As shown in FIG. 3A, two through substrate holes 302 and 304 may be formed extending through the core dielectric 110. In some aspects, the through substrate holes 302 and 304 may be formed based on mechanical drilling or laser drilling. In some aspects at this stage, thin conductive films 306 and 308 (e.g., from the CCL core) may still be attached to the first surface 112 and the second surface 114 of the core dielectric 110.

As shown in FIG. 3B, a structure 300B may be formed based on the structure 300A by forming through substrate via structures 116 and 118 in the through substrate holes 302 and 304, and forming a portion of the first conductive traces 124 on the first surface 112 and a portion of the second conductive traces 134 on the second surface 114 by patterning a mask covering the conductive films 306 and 308, and plating a conductive material and cleaning based on the patterned mask. In some aspects, the conductive material for forming the portion of the first conductive traces 124 and the portion of the second conductive traces 134 in FIG. 3B may include copper.

As shown in FIG. 3C, a structure 300C may be formed based on the structure 300B by forming an opening 312 in the core dielectric 110, which may define a cavity 146 of the core dielectric 110. In some aspects, the opening 312 (and hence the cavity 146) may be formed based on mechanical drilling or laser drilling from either the first side of the core dielectric 110 (corresponding to the first surface 112) or the second side of the core dielectric 110 (corresponding to the second surface 114). In some aspects, the opening 312 may be configured to receive an embedded component (e.g., the third embedded component 170) that has a thickness comparable to, or less than, the thickness H0 of the core dielectric 110. As shown in FIG. 3C, the cavity 146 may extend through the core dielectric 110 from the first surface 112 to the second surface 114 of the core dielectric. In some aspects, the opening 312 (as well as the cavity 146) may have an opening through either the first surface 112 to the second surface 114 of the core dielectric 110, without passing through the entire thickness of the core dielectric 110.

As shown in FIG. 3D, a structure 300D may be formed based on the structure 300C by attaching a tape 314 on a surface of the core dielectric 110 (e.g., the second surface 114 in this example) by tape lamination, and disposing an embedded component (e.g., the third embedded component 170) in the opening 312 and in the cavity 146 of the core dielectric 110. In some aspects, the conductive terminals of the embedded component (e.g., the conductive terminals 172) may be attached to the tape 314.

As shown in FIG. 3E, a structure 300E may be formed based on the structure 300D by forming a first number N1 of dielectric layers, which constitute a portion of a first plurality of dielectric layers 122 of a first metallization structure (e.g., the first metallization structure 120 in FIG. 1); and forming a second number N2 of dielectric layers, which constitute a portion of a second plurality of dielectric layers 132 of a second metallization structure (e.g., the second metallization structure 130 in FIG. 1). In some aspects, various conductive traces (e.g., a portion of the first conductive traces 124 in FIG. 1) and conductive vias (e.g., a portion of the first conductive vias 126 in FIG. 1) may be formed in the first number N1 of dielectric layers. Also, various conductive traces (e.g., a portion of the second conductive traces 134 in FIG. 1) and conductive vias (e.g., a portion of the second conductive vias 136 in FIG. 1) may be formed in the second number N2 of dielectric layers. In some aspects, the conductive material for forming the portion of the first conductive traces 124 and the portion of the second conductive traces 134 in FIG. 3E may include copper.

In some aspects, each layer of the first number N1 of dielectric layers and the second number N2 of dielectric layers may be formed based on attaching a build-up dielectric film to the core dielectric 110 or on top of a previous dielectric layer, drilling openings for forming conductive vias in that build-up dielectric film, and then forming conductive patterns on that build-up dielectric film to become conductive traces and filling the holes to become conductive vias. In some aspects, after the dielectric layer immediately adjacent the first surface 112 of the core dielectric 110 is formed, the tape 314 may be removed such that the dielectric layer immediately adjacent the second surface 114 of the core dielectric 110 may be subsequently formed. In some aspects, the build-up dielectric film may be a pre-preg dielectric film, an ABF, or the like.

In some aspects, the first number N1 and the second number N2 may be determined based on a thickness of an embedded component (e.g., the first embedded component 150) to be subsequently embedded in the structure 300E. In some aspects, the first number N1 may equal the second number N2. In this example, the first number N1 equals the second number N2 and equals 2. In some aspects, the first number N1 and the second number N2 may be different.

As shown in FIG. 3F, a structure 300F may be formed based on the structure 300E by forming an opening 322 in the structure 300E, which may define a cavity 142 of the core dielectric 110. In some aspects, the opening 322 may be formed based on mechanical drilling or laser drilling from either the first side of the core dielectric 110 or the second side of the core dielectric 110. In some aspects, the opening 322 may be configured to receive an embedded component (e.g., the first embedded component 150) that has a thickness comparable to, or less than, the thickness of the structure 300E. As shown in FIG. 3F, the cavity 142 may extend through the core dielectric 110 from the first surface 112 to the second surface 114 of the core dielectric. In some aspects, the opening 322 may have an opening at a first side of the structure 300F, an opening at a second side of the structure 300F, or both.

As shown in FIG. 3G, a structure 300G may be formed based on the structure 300F by attaching a tape 324 on a surface of the structure 300F (e.g., au upper surface as depicted in FIG. 3G) by tape lamination, and disposing an embedded component (e.g., the first embedded component 150) in the opening 322. In some aspects, the conductive terminals of the embedded component (e.g., the conductive terminals 152) may be attached to the tape 324.

As shown in FIG. 3H, a structure 300H may be formed based on the structure 300G by forming a third number N3 of dielectric layers, which constitute another portion of the first plurality of dielectric layers 122 of the first metallization structure (e.g., the first metallization structure 120 in FIG. 1); and forming a fourth number N4 of dielectric layers, which constitute another portion of the second plurality of dielectric layers 132 of the second metallization structure (e.g., the second metallization structure 130 in FIG. 1). In some aspects, various conductive traces (e.g., another portion of the first conductive traces 124 in FIG. 1) and conductive vias (e.g., another portion of the first conductive vias 126 in FIG. 1) may be formed in the third number N3 of dielectric layers. Also, various conductive traces (e.g., another portion of the second conductive traces 134 in FIG. 1) and conductive vias (e.g., another portion of the second conductive vias 136 in FIG. 1) may be formed in the fourth number N4 of dielectric layers. In some aspects, the conductive material for forming the portion of the first conductive traces 124 and the portion of the second conductive traces 134 in FIG. 3H may include copper.

In some aspects, each layer of the third number N3 of dielectric layers and the fourth number N4 of dielectric layers may be formed based on attaching a build-up dielectric film on top of a previous dielectric layer, drilling openings for forming conductive vias in that build-up dielectric film, and then forming conductive patterns on that build-up dielectric film to become conductive traces and filling the holes to become conductive vias. In some aspects, after the dielectric layer immediately adjacent the second number N2 of dielectric layers is formed, the tape 324 may be removed such that the dielectric layer immediately adjacent the first number N1 of dielectric layers may be subsequently formed. In some aspects, the build-up dielectric film may also be a pre-preg dielectric film, an ABF, or the like.

In some aspects, the third number N3 and the fourth number N4 (together with the first number N1 and the second number N2) may be determined based on a thickness of an embedded component (e.g., the second embedded component 160) to be subsequently embedded in the structure 300H. In some aspects, the third number N3 may equal the fourth number N4. In this example, the third number N3 equals the fourth number N4 and equals 3. In some aspects, the third number N3 and the fourth number N4 may be different.

As shown in FIG. 3I, a structure 300I may be formed based on the structure 300H by forming an opening 332 in the structure 300H, which may define a cavity 144 of the core dielectric 110. In some aspects, the opening 332 may be formed based on mechanical drilling or laser drilling from either the first side of the core dielectric 110 or the second side of the core dielectric 110. In some aspects, the opening 332 may be configured to receive an embedded component (e.g., the second embedded component 160) that has a thickness comparable to, or less than, the thickness of the structure 300H. As shown in FIG. 3I, the cavity 144 may extend through the core dielectric 110 from the first surface 112 to the second surface 114 of the core dielectric. In some aspects, the opening 332 may have an opening at a first side of the structure 300I, an opening at a second side of the structure 300I, or both.

As shown in FIG. 3J, a structure 300J may be formed based on the structure 300I by attaching a tape 334 on a surface of the structure 300I (e.g., a lower surface as depicted in FIG. 3J) by tape lamination, and disposing an embedded component (e.g., the second embedded component 160) in the opening 332. In some aspects, the conductive terminals of the embedded component (e.g., the conductive terminals 162) may be attached to the tape 334. In this example, the embedded component 160 may include a chip 164 and a dummy structure 166 stacked one over the other in order to increase the overall thickness of the embedded component 160. In some aspects, any of the embedded components described in FIGS. 3D-3J may include (e.g., in the chip of the embedded component) a capacitive device, an inductive device, a resistive device, an active device, or any combination thereof.

As shown in FIG. 3K, a structure 300K may be formed based on the structure 300J by forming a fifth number N5 of dielectric layers, which constitute yet another portion of the first plurality of dielectric layers 122 of the first metallization structure (e.g., the first metallization structure 120 in FIG. 1) and forming a sixth number N6 of dielectric layers, which constitute yet another portion of the second plurality of dielectric layers 132 of the second metallization structure (e.g., the second metallization structure 130 in FIG. 1). In some aspects, various conductive traces (e.g., yet another portion of the first conductive traces 124 in FIG. 1) and conductive vias (e.g., yet another portion of the first conductive vias 126 in FIG. 1) may be formed in the fifth number N5 of dielectric layers. Also, various conductive traces (e.g., yet another portion of the second conductive traces 134 in FIG. 1) and conductive vias (e.g., yet another portion of the second conductive vias 136 in FIG. 1) may be formed in the sixth number N6 of dielectric layers. In some aspects, the conductive material for forming the portion of the first conductive traces 124 and the portion of the second conductive traces 134 in FIG. 3K may include copper.

In some aspects, each layer of the fifth number N5 of dielectric layers and the sixth number N6 of dielectric layers may be formed based on attaching a build-up dielectric film on top of a previous dielectric layer, drilling openings for forming conductive vias in that build-up dielectric film, and then forming conductive patterns on that build-up dielectric film to become conductive traces and filling the holes to become conductive vias. In some aspects, after the dielectric layer immediately adjacent the third number N3 of dielectric layers is formed, the tape 334 may be removed such that the dielectric layer immediately adjacent the fourth number N4 of dielectric layers may be subsequently formed. In some aspects, the build-up dielectric film may also be a pre-preg dielectric film, an ABF, or the like.

In some aspects, the fifth number N5 and the sixth number N6 (together with the first number N1, the second number N2, the third number N3, and the fourth number N4) may be determined based on the routing resources that are needed for forming the first metallization structure 120 and the second metallization structure 130. In some aspects, the fifth number N5 may equal the sixth number N6. In this example, the fifth number N5 equals the sixth number N6 and equals 5. In some aspects, the fifth number N5 and the sixth number N6 may be different.

After forming the first plurality of dielectric layers 122 and the second plurality of dielectric layers 132 together with all the conductive traces and conductive vias therein, a first protective layer 128 may be formed on the first plurality of dielectric layers 122, and a second protective layer 138 may be formed on the second plurality of dielectric layers 132. In some aspects, the first protective layer 128 and the second protective layer 138 may include openings exposing a portion of an upper surface of the first metallization structure 120 and a portion of a lower surface of the second metallization structure 130 for electrical connection with an external component or circuitry.

In some aspects, the structure 300K may correspond to the EPS structure 100 of a package substrate in FIG. 1. In some aspects, further processes may be performed to form conductive structures (e.g., solder bumps, copper pillar bumps, micro-bumps, or the like) through the openings of the first protective layer 128 and the second protective layer 138.

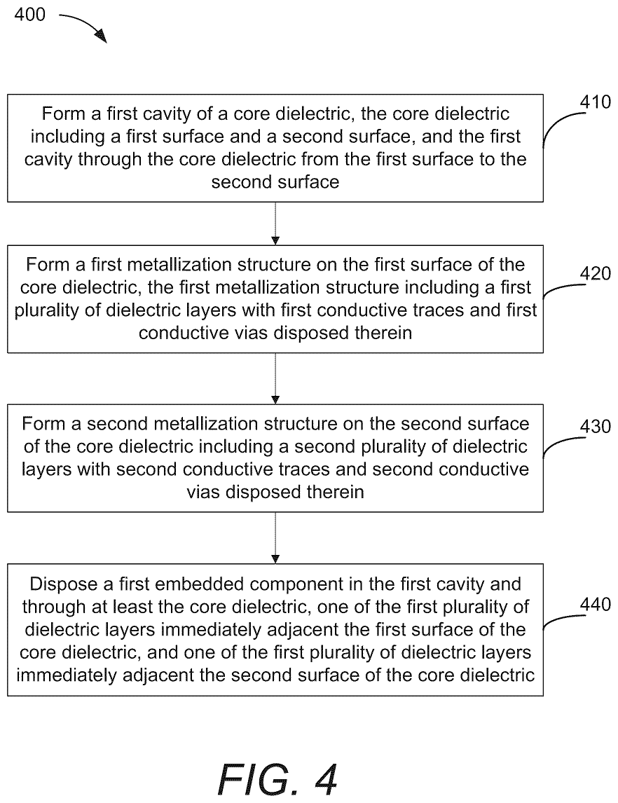

FIG. 4 illustrates a method 400 for manufacturing a package substrate (e.g., a package substrate that includes the EPS structure 100 in FIG. 1 or the structure 300K in FIG. 3K), according to aspects of the disclosure. In some aspects, FIGS. 3A-3K may show the corresponding structures at various stages of the method 400. Accordingly, various components illustrated in FIGS. 1 and 3A-3K may be used as non-limiting examples of the method 400.

At operation 410, a first cavity (e.g., the cavity 142) of a core dielectric (e.g., the core dielectric 110) may be formed. In some aspects, the core dielectric may include a first surface (e.g., the first surface 112) and a second surface (e.g., the second surface 114), and the first cavity may be through the core dielectric from the first surface to the second surface. In some aspects, the resulting structure after the operation 410 may correspond to the structure 300F in FIG. 3F. In some aspects, the first cavity may be formed as part of a process of forming an opening (e.g., the opening 322) through the structure 300E. In some aspects, the opening (including the first cavity) may be formed based on mechanical drilling or laser drilling. In some aspects, the core dielectric may include resin or fiber-reinforced composite resin.

At operation 420, a first metallization structure (e.g., the first metallization structure 120) may be formed on the first surface of the core dielectric. In some aspects, the first metallization structure may include a first plurality of dielectric layers (e.g., the first plurality of dielectric layers 122) with first conductive traces and first conductive vias disposed therein. In some aspects, the forming the first metallization structure may include forming a first number (e.g., N1) of dielectric layers of the first plurality of dielectric layers prior to disposing a first embedded component (e.g., the first embedded component 150) and forming a remaining portion of the first plurality of dielectric layers after disposing the first embedded component. In some aspects, the first plurality of dielectric layers may include 6 or more dielectric layers.

At operation 430, a second metallization structure (e.g., the second metallization structure 130) may be formed on the second surface of the core dielectric. In some aspects, the second metallization structure may include a second plurality of dielectric layers (e.g., the second plurality of dielectric layers 132) with second conductive traces and second conductive vias disposed therein. In some aspects, the forming the second metallization structure may include forming a second number (e.g., N2) of dielectric layers of the second plurality of dielectric layers prior to disposing the first embedded component (e.g., the first embedded component 150) and forming a remaining portion of the second plurality of dielectric layers after disposing the first embedded component. In some aspects, the second plurality of dielectric layers may include 6 or more dielectric layers.

In some aspects, the first plurality of dielectric layers and the second plurality of dielectric layers may be formed based on build-up dielectric films and forming the conductive traces and conductive vias therein on a layer-by-layer basis. In some aspects, each layer of the dielectric layers in operations 420 and 430 may be formed based on attaching a respective build-up dielectric film on top of a previous dielectric layer, drilling openings for forming conductive vias in that build-up dielectric film, and then forming conductive patterns on that build-up dielectric film to become conductive traces and filling the holes to become conductive vias. In some aspects, the build-up dielectric film may also be a pre-preg dielectric film, an ABF, or the like.

At operation 440, a first embedded component (e.g., the first embedded component 150) may be disposed in the first cavity and through at least the core dielectric, one of the first plurality of dielectric layers immediately adjacent the first surface of the core dielectric, and one of the first plurality of dielectric layers immediately adjacent the second surface of the core dielectric.

In some aspects, the method 400 may further include forming a first opening through the first number of dielectric layers of the first plurality of dielectric layers, the core dielectric, and the second number of dielectric layers of the second plurality of dielectric layers, where a portion of the first opening through the core dielectric becoming the first cavity of the core dielectric. In some aspects, the first embedded component may be disposed in the first opening. In some aspects, the forming the first metallization structure may further include, after the first embedded component is disposed in the first opening, forming the remaining portion of the first plurality of dielectric layers. In some aspects, the forming the second metallization structure may further include, after the first embedded component is disposed in the first opening, forming the remaining portion of the second plurality of dielectric layers. In some aspects, the resulting structure after the operation 440 may correspond to the structure 300K in FIG. 3K or the EPS structure 100 in FIG. 1.

In some aspects, the method may further include forming a second cavity (e.g., the cavity 144) of the core dielectric through the core dielectric from the first surface to the second surface. The method may further include disposing a second embedded component (e.g., the second embedded component 160) in the second cavity and through at least the core dielectric, the one of the first plurality of dielectric layers immediately adjacent the first surface of the core dielectric, and the one of the first plurality of dielectric layers immediately adjacent the second surface of the core dielectric. In some aspects, a first thickness of the first embedded component and a second thickness of the second embedded component may be different.

In some aspects, the first embedded component may include first conductive terminals (e.g., the first conductive terminals 152), and the second embedded component may include second conductive terminals (e.g., the second conductive terminals 162). In some aspects, the first conductive terminals and the second conductive terminals may be disposed at a same side of the core dielectric or at different sides of the core dielectric.

In some aspects, the method may further include forming a third cavity (e.g., the cavity 146) in the core dielectric or through the core dielectric. In some aspects, the third cavity may have an opening through the first surface, an opening through the second surface, or both. In some aspects, the method may further include disposing a third embedded component (e.g., the third embedded component 170) in the third cavity of the core dielectric, without passing through the one of the first plurality of dielectric layers immediately adjacent the first surface of the core dielectric, and without passing through the one of the second plurality of dielectric layers immediately adjacent the second surface of the core dielectric.

In some aspects, any of the first embedded component, the second embedded component, and/or the third embedded component may include a chip, or the chip stacked on a dummy structure. In some aspects, any of the first embedded component, the second embedded component, and/or the third embedded component may include a capacitive device, an inductive device, a resistive device, an active device, or any combination thereof.

A technical advantage of the method 400 is for formation of a package substrate that may be suitable of accommodating an embedded component of any thickness. In some aspects, the thickness of a core dielectric of the EPS structure of the package substrate may not be limited by the thicknesses of the embedded components to be included therein. In some aspects, by moving the conductive terminals of an embedded component closer to an outer surface of the EPS structure, the AC-L of a conductive path from the embedded component to the external circuitry may be reduced to a desirable level. Accordingly, the number of dielectric/conductive layers of the EPS structure may be increased to allow a more complicated routing scheme while still reducing the AC-L regarding the embedded component.

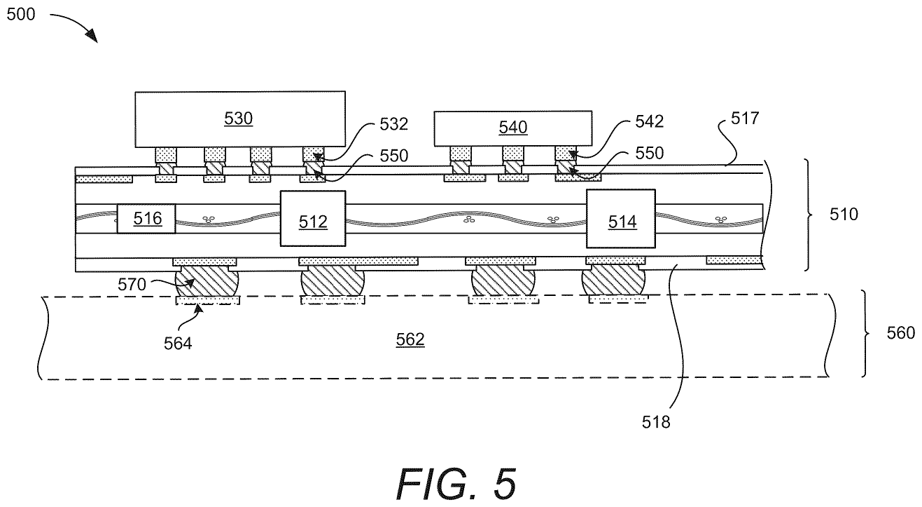

FIG. 5 illustrates a simplified cross-sectional view of an IC package 500 that includes a package substrate 510 having an EPS structure as described above, according to aspects of the disclosure. In some aspects, the package substrate 510 may include embedded components 512, 514, and 516 that may correspond to the embedded components 150, 160, and 170 in FIG. 1.

As shown in FIG. 5, the package substrate 510 may include a first protective layer 517 on an upper side of the package substrate 510 and a second protective layer 518 on a lower side of the package substrate 510. In some aspects, the protective layers 517 and 518 may correspond to the protective layers 128 and 138 in FIG. 1. The IC package 500 may include an IC device 530 having conductive terminals 532 and an integrated passive device 540 having conductive terminals 542. The IC device 530 and the integrated passive device 540 may be mounted on the package substrate 510 with the conductive terminals 532 and 542 coupled to conductive traces of the package substrate 510 exposed by openings of the protective layer 517 through conductive structures (e.g., solder bumps) 550.

Moreover, as shown in FIG. 5, the IC package 500 may be mounted on a printed circuit board (PCB) 560 through a plurality of solder interconnects 570. The PCB 560 may include at least one board dielectric layer 562 and a plurality of board interconnects 564.

In some aspects, the IC package 500 may be implemented in a radio frequency (RF) package. The RF package may be a radio frequency front end (RFFE) package. In some aspects, the IC package 500 may be configured to provide WiFi communication and/or cellular communication (e.g., 2G, 3G, 4G, 5G). In some aspects, the IC package 500 may be configured to support Global System for Mobile (GSM) Communications, Universal Mobile Telecommunications System (UMTS), and/or Long-Term Evolution (LTE). In some aspects, the IC package 500 may be configured to transmit and receive signals having different frequencies and/or communication protocols.

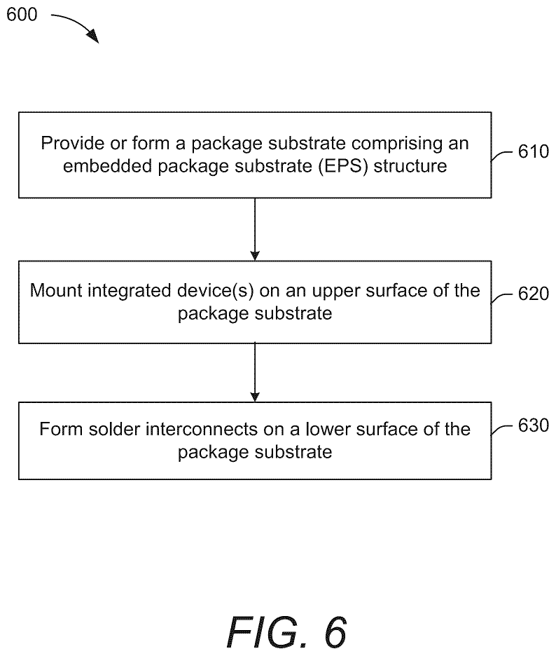

FIG. 6 illustrates a method 600 of fabricating an IC package that includes an EPS structure, according to aspects of the disclosure. In some implementations, the method 600 of FIG. 6 may be used to fabricate the IC package 500 in FIG. 5 as a non-limiting example.

It should be noted that the method of FIG. 6 may combine one or more processes in order to simplify and/or clarify the method for fabricating a package that includes a package substrate having an EPS structure. In some implementations, the order of the processes may be changed or modified.

At operation 610, a package substrate (e.g., the package substate 510 having the EPS structure 100 described in this disclosure) may be formed (e.g., as illustrated in FIGS. 3A-4) or provided. In some aspects, the package substrate may be provided by a supplier.

At operation 620, at least one integrated device (e.g., the IC device 530 and/or the integrated passive device 540) may be mounted on an upper surface of the package substrate. For example, as shown in FIG. 5, the IC device 530 may be coupled to the package substate 510 through the conductive terminals 532 and the conductive structures 550. In some aspects, the conductive structures may be formed based on a solder reflow process.

At operation 630, a plurality of solder interconnects (e.g., the solder interconnects 570) may be formed on a lower surface of the package substate. In some aspects, the solder interconnects may be formed based on a solder reflow process.

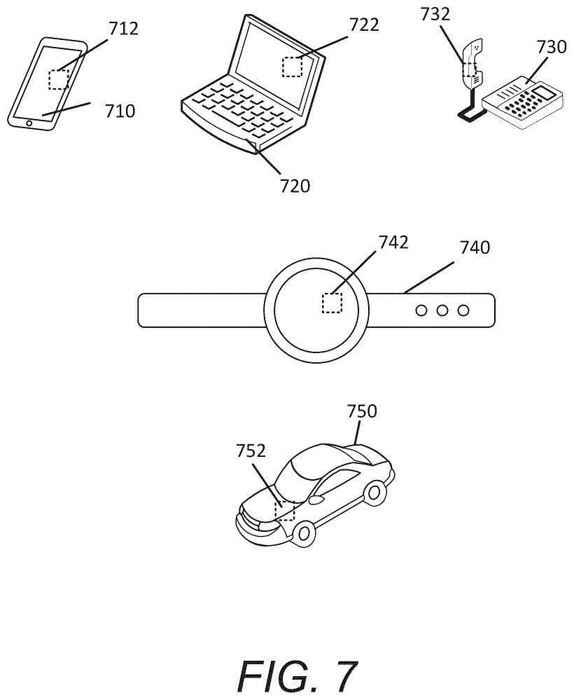

FIG. 7 illustrates various electronic devices that may integrate an IC package that includes a package substrate described herein, according to aspects of the disclosure. For example, a mobile phone device 710, a laptop computer device 720, a fixed location terminal device 730, a wearable device 740, or an electronic device onboard an automotive vehicle 750 may respectively include IC packages 712, 722, 732, 742, and 752 (e.g., corresponding to an IC package that includes the EPS structure based on the examples described above with reference to FIGS. 1-6). The devices 710, 720, 730, and 740 and the vehicle 750 illustrated in FIG. 7 are merely exemplary. Other apparatuses or devices that may feature the IC package as described herein may include, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A package substrate, comprising: a core dielectric that includes a first surface, a second surface, and a first cavity through the core dielectric from the first surface to the second surface; a first metallization structure on the first surface of the core dielectric, the first metallization structure including a first plurality of dielectric layers with first conductive traces and first conductive vias disposed therein; a second metallization structure on the second surface of the core dielectric including a second plurality of dielectric layers with second conductive traces and second conductive vias disposed therein; and a first embedded component disposed in the first cavity and through at least the core dielectric, one of the first plurality of dielectric layers immediately adjacent the first surface of the core dielectric, and one of the second plurality of dielectric layers immediately adjacent the second surface of the core dielectric.

Clause 2. The package substrate of clause 1, wherein: the first embedded component is disposed through a first number of dielectric layers of the first plurality of dielectric layers and through a second number of dielectric layers of the second plurality of dielectric layers, and the first number equals the second number.

Clause 3. The package substrate of any of clauses 1 to 2, further comprising: a second embedded component disposed in a second cavity of the core dielectric and through at least the core dielectric, the one of the first plurality of dielectric layers immediately adjacent the first surface of the core dielectric, and the one of the second plurality of dielectric layers immediately adjacent the second surface of the core dielectric, wherein a first thickness of the first embedded component and a second thickness of the second embedded component are different.

Clause 4. The package substrate of clause 3, wherein: the first embedded component includes first conductive terminals, the second embedded component includes second conductive terminals, and the first conductive terminals and the second conductive terminals are disposed at a same side of the core dielectric or at different sides of the core dielectric.

Clause 5. The package substrate of any of clauses 1 to 4, wherein the first embedded component comprises: a chip, or the chip and a dummy structure stacked one over the other.

Clause 6. The package substrate of any of clauses 1 to 5, further comprising: a third embedded component disposed in a third cavity of the core dielectric, without passing through the one of the first plurality of dielectric layers immediately adjacent the first surface of the core dielectric, and without passing through the one of the second plurality of dielectric layers immediately adjacent the second surface of the core dielectric.

Clause 7. The package substrate of any of clauses 1 to 6, wherein: the first plurality of dielectric layers includes six or more dielectric layers, and the second plurality of dielectric layers includes six or more dielectric layers.

Clause 8. The package substrate of any of clauses 1 to 7, wherein the first embedded component comprises: a capacitive device; an inductive device; a resistive device; an active device; or any combination thereof.

Clause 9. The package substrate of any of clauses 1 to 8, wherein: the core dielectric comprises resin or fiber-reinforced composite resin, and the first plurality of dielectric layers and the second plurality of dielectric layers are formed based on build-up dielectric films.

Clause 10. A method of manufacturing a package substrate, comprising: forming a first cavity of a core dielectric, the core dielectric including a first surface and a second surface, and the first cavity through the core dielectric from the first surface to the second surface; forming a first metallization structure on the first surface of the core dielectric, the first metallization structure including a first plurality of dielectric layers with first conductive traces and first conductive vias disposed therein; forming a second metallization structure on the second surface of the core dielectric including a second plurality of dielectric layers with second conductive traces and second conductive vias disposed therein; and disposing a first embedded component in the first cavity and through at least the core dielectric, one of the first plurality of dielectric layers immediately adjacent the first surface of the core dielectric, and one of the first plurality of dielectric layers immediately adjacent the second surface of the core dielectric.

Clause 11. The method of clause 10, wherein: the forming the first metallization structure comprises forming a first number of dielectric layers of the first plurality of dielectric layers, the forming the second metallization structure comprises forming a second number of dielectric layers of the second plurality of dielectric layers, and the method further comprises forming a first opening through the first number of dielectric layers of the first plurality of dielectric layers, the core dielectric, and the second number of dielectric layers of the second plurality of dielectric layers, wherein a portion of the first opening through the core dielectric becoming the first cavity of the core dielectric.

Clause 12. The method of clause 11, wherein: the first embedded component is disposed in the first opening, the forming the first metallization structure further comprises, after the first embedded component is disposed in the first opening, forming a remaining portion of the first plurality of dielectric layers, and the forming the second metallization structure further comprises, after the first embedded component is disposed in the first opening, forming a remaining portion of the second plurality of dielectric layers.

Clause 13. The method of any of clauses 10 to 12, further comprising: forming a second cavity of the core dielectric through the core dielectric from the first surface to the second surface; and disposing a second embedded component in the second cavity and through at least the core dielectric, the one of the first plurality of dielectric layers immediately adjacent the first surface of the core dielectric, and the one of the first plurality of dielectric layers immediately adjacent the second surface of the core dielectric, wherein a first thickness of the first embedded component and a second thickness of the second embedded component are different.

Clause 14. The method of clause 13, wherein: the first embedded component includes first conductive terminals, the second embedded component includes second conductive terminals, and the first conductive terminals and the second conductive terminals are disposed at a same side of the core dielectric or at different sides of the core dielectric.

Clause 15. The method of any of clauses 10 to 14, wherein the first embedded component comprises: a chip, or the chip stacked on a dummy structure.

Clause 16. The method of any of clauses 10 to 15, further comprising: forming a third cavity of the core dielectric in or through the core dielectric, the third cavity having an opening through the first surface, an opening through the second surface, or both; and disposing a third embedded component in or through the third cavity of the core dielectric, without passing through the one of the first plurality of dielectric layers immediately adjacent the first surface of the core dielectric, and without passing through the one of the second plurality of dielectric layers immediately adjacent the second surface of the core dielectric.

Clause 17. The method of any of clauses 10 to 16, wherein: the first plurality of dielectric layers includes 6 or more dielectric layers, and the second plurality of dielectric layers includes 6 or more dielectric layers.

Clause 18. The method of any of clauses 10 to 17, wherein the first embedded component comprises: a capacitive device; an inductive device; a resistive device; an active device; or any combination thereof.

Clause 19. The method of any of clauses 10 to 18, wherein: the core dielectric comprises resin or fiber-reinforced composite resin, and the first plurality of dielectric layers and the second plurality of dielectric layers are formed based on build-up dielectric films.

Clause 20. An electronic device, comprising: a package substrate that includes: a core dielectric that includes a first surface, a second surface, and a first cavity through the core dielectric from the first surface to the second surface; a first metallization structure on the first surface of the core dielectric, the first metallization structure including a first plurality of dielectric layers with first conductive traces and first conductive vias disposed therein; a second metallization structure on the second surface of the core dielectric including a second plurality of dielectric layers with second conductive traces and second conductive vias disposed therein; and a first embedded component disposed in the first cavity and through at least the core dielectric, one of the first plurality of dielectric layers immediately adjacent the first surface of the core dielectric, and one of the first plurality of dielectric layers immediately adjacent the second surface of the core dielectric.

Clause 21. The electronic device of clause 20, wherein: the first embedded component is disposed through a first number of dielectric layers and through a second number of dielectric layers, and the first number equals the second number.

Clause 22. The electronic device of any of clauses 20 to 21, wherein the package substrate further comprises: a second embedded component disposed in a second cavity of the core dielectric and through at least the core dielectric, the one of the first plurality of dielectric layers immediately adjacent the first surface of the core dielectric, and the one of the second plurality of dielectric layers immediately adjacent the second surface of the core dielectric, wherein a first thickness of the first embedded component and a second thickness of the second embedded component are different.

Clause 23. The electronic device of clause 22, wherein: the first embedded component includes first conductive terminals, the second embedded component includes second conductive terminals, and the first conductive terminals and the second conductive terminals are disposed at a same side of the core dielectric or at different sides of the core dielectric.

Clause 24. The electronic device of any of clauses 20 to 23, wherein the first embedded component comprises: a chip, or the chip stacked on a dummy structure.

Clause 25. The electronic device of any of clauses 20 to 24, wherein the package substrate further comprises: a third embedded component disposed in a third cavity of the core dielectric, without passing through the one of the first plurality of dielectric layers immediately adjacent the first surface of the core dielectric, and without passing through the one of the second plurality of dielectric layers immediately adjacent the second surface of the core dielectric.

Clause 26. The electronic device of any of clauses 20 to 25, wherein: the first plurality of dielectric layers includes 6 or more dielectric layers, and the second plurality of dielectric layers includes 6 or more dielectric layers.

Clause 27. The electronic device of any of clauses 20 to 26, wherein the first embedded component comprises: a capacitive device; an inductive device; a resistive device; an active device; or any combination thereof.

Clause 28. The electronic device of any of clauses 20 to 27, wherein: the core dielectric comprises resin or fiber-reinforced composite resin, and the first plurality of dielectric layers and the second plurality of dielectric layers are formed based on build-up dielectric films.

Clause 29. The electronic device of any of clauses 20 to 28, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. A package substrate, comprising:
a core dielectric that includes a first surface, a second surface, and a first cavity through the core dielectric from the first surface to the second surface;
a first metallization structure on the first surface of the core dielectric, the first metallization structure including a first plurality of dielectric layers with first conductive traces and first conductive vias disposed therein;
a second metallization structure on the second surface of the core dielectric including a second plurality of dielectric layers with second conductive traces and second conductive vias disposed therein; and
a first embedded component disposed in the first cavity and through at least the core dielectric, one of the first plurality of dielectric layers immediately adjacent the first surface of the core dielectric, and one of the second plurality of dielectric layers immediately adjacent the second surface of the core dielectric.

2. The package substrate of claim 1, wherein:
the first embedded component is disposed through a first number of dielectric layers of the first plurality of dielectric layers and through a second number of dielectric layers of the second plurality of dielectric layers, and
the first number equals the second number.

3. The package substrate of claim 1, further comprising:
a second embedded component disposed in a second cavity of the core dielectric and through at least the core dielectric, the one of the first plurality of dielectric layers immediately adjacent the first surface of the core dielectric, and the one of the second plurality of dielectric layers immediately adjacent the second surface of the core dielectric,
wherein a first thickness of the first embedded component and a second thickness of the second embedded component are different.

4. The package substrate of claim 3, wherein:
the first embedded component includes first conductive terminals,
the second embedded component includes second conductive terminals, and
the first conductive terminals and the second conductive terminals are disposed at a same side of the core dielectric or at different sides of the core dielectric.

5. The package substrate of claim 1, wherein the first embedded component comprises:
a chip, or
the chip and a dummy structure stacked one over the other.

6. The package substrate of claim 1, further comprising:
a third embedded component disposed in a third cavity of the core dielectric, without passing through the one of the first plurality of dielectric layers immediately adjacent the first surface of the core dielectric, and without passing through the one of the second plurality of dielectric layers immediately adjacent the second surface of the core dielectric.

7. The package substrate of claim 1, wherein:
the first plurality of dielectric layers includes six or more dielectric layers, and
the second plurality of dielectric layers includes six or more dielectric layers.

8. The package substrate of claim 1, wherein the first embedded component comprises:
a capacitive device;
an inductive device;
a resistive device;
an active device; or
any combination thereof.

9. The package substrate of claim 1, wherein:
the core dielectric comprises resin or fiber-reinforced composite resin, and
the first plurality of dielectric layers and the second plurality of dielectric layers are formed based on build-up dielectric films.

10. A method of manufacturing a package substrate, comprising:
forming a first cavity of a core dielectric, the core dielectric including a first surface and a second surface, and the first cavity through the core dielectric from the first surface to the second surface;
forming a first metallization structure on the first surface of the core dielectric, the first metallization structure including a first plurality of dielectric layers with first conductive traces and first conductive vias disposed therein;
forming a second metallization structure on the second surface of the core dielectric including a second plurality of dielectric layers with second conductive traces and second conductive vias disposed therein; and
disposing a first embedded component in the first cavity and through at least the core dielectric, one of the first plurality of dielectric layers immediately adjacent the first surface of the core dielectric, and one of the first plurality of dielectric layers immediately adjacent the second surface of the core dielectric.

11. The method of claim 10, wherein:
the forming the first metallization structure comprises forming a first number of dielectric layers of the first plurality of dielectric layers,
the forming the second metallization structure comprises forming a second number of dielectric layers of the second plurality of dielectric layers, and
the method further comprises forming a first opening through the first number of dielectric layers of the first plurality of dielectric layers, the core dielectric, and the second number of dielectric layers of the second plurality of dielectric layers, wherein a portion of the first opening through the core dielectric becoming the first cavity of the core dielectric.

12. The method of claim 11, wherein:
the first embedded component is disposed in the first opening,
the forming the first metallization structure further comprises, after the first embedded component is disposed in the first opening, forming a remaining portion of the first plurality of dielectric layers, and
the forming the second metallization structure further comprises, after the first embedded component is disposed in the first opening, forming a remaining portion of the second plurality of dielectric layers.

13. The method of claim 10, further comprising:
forming a second cavity of the core dielectric through the core dielectric from the first surface to the second surface; and
disposing a second embedded component in the second cavity and through at least the core dielectric, the one of the first plurality of dielectric layers immediately adjacent the first surface of the core dielectric, and the one of the first plurality of dielectric layers immediately adjacent the second surface of the core dielectric,
wherein a first thickness of the first embedded component and a second thickness of the second embedded component are different.

14. The method of claim 10, wherein the first embedded component comprises:
a chip, or
the chip stacked on a dummy structure.

15. The method of claim 10, further comprising:
forming a third cavity of the core dielectric in or through the core dielectric, the third cavity having an opening through the first surface, an opening through the second surface, or both; and
disposing a third embedded component in the third cavity of the core dielectric, without passing through the one of the first plurality of dielectric layers immediately adjacent the first surface of the core dielectric, and without passing through the one of the second plurality of dielectric layers immediately adjacent the second surface of the core dielectric.

16. An electronic device, comprising:
a package substrate that includes:
a core dielectric that includes a first surface, a second surface, and a first cavity through the core dielectric from the first surface to the second surface;
a first metallization structure on the first surface of the core dielectric, the first metallization structure including a first plurality of dielectric layers with first conductive traces and first conductive vias disposed therein;
a second metallization structure on the second surface of the core dielectric including a second plurality of dielectric layers with second conductive traces and second conductive vias disposed therein; and
a first embedded component disposed in the first cavity and through at least the core dielectric, one of the first plurality of dielectric layers immediately adjacent the first surface of the core dielectric, and one of the first plurality of dielectric layers immediately adjacent the second surface of the core dielectric.

17. The electronic device of claim 16, wherein the package substrate further comprises:
a second embedded component disposed in a second cavity of the core dielectric and through at least the core dielectric, the one of the first plurality of dielectric layers immediately adjacent the first surface of the core dielectric, and the one of the second plurality of dielectric layers immediately adjacent the second surface of the core dielectric,
wherein a first thickness of the first embedded component and a second thickness of the second embedded component are different.

18. The electronic device of claim 16, wherein the first embedded component comprises:
a chip, or
the chip stacked on a dummy structure.

19. The electronic device of claim 16, wherein:
the core dielectric comprises resin or fiber-reinforced composite resin, and
the first plurality of dielectric layers and the second plurality of dielectric layers are formed based on build-up dielectric films.

20. The electronic device of claim 16, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
